(19) United States
(12) Patent Application Publication
(10) Pub. No.: US 2011/0115035 A1
(43) Pub. Date: May 19, 2011

(54) General strength and sensitivity enhancement method for micromachined device

(75) Inventors: Jung-Tang Huang, Taipei (TW); Ming-Jhe Lin, Taipei (TW); Hou-Jun Hsu, Taipei (TW)

(73) Assignee: Jung-Tang Huang

(21) Appl. No.: 12/807,658

(22) Filed: Sep. 13, 2010

(30) Foreign Application Priority Data
Sep. 8, 2009 (TW) 098130194

(51) Int. Cl. H01L 23/14; H01L 21/445

(52) U.S. Cl. 257/414; 257/618; 438/678; 257/E23.005; 257/E21.479

(57) ABSTRACT

This invention disclosed a method to strengthen structure and enhance sensitivity for CMOS-MEMS micro-machined devices which include micro-motion sensor, micro-actuator and RF switch. The steps of the said method contain defining deposited region by metal and passivation layer, forming a cavity for depositing metal structure by lithography process, depositing metal structure on the top metal layer of micromachined structure by Electroless plating, polishing process and etching process. The method aims at strengthening structures and minimizing CMOS-MEMS device size. Furthermore, this method can also be applied to inertia sensors such as accelerometer or gyroscope, which can enhance sensitivity and capacitive value, and deal with curl issues for suspended CMOS-MEMS devices.

### FIELD OF INVENTION

This invention disclosed a method to strengthen structure and enhance sensitivity for CMOS-MEMS micro-machined devices which include micro motion sensor, micro actuator and RF switch. The steps of the said method contain defining the deposited region by metal layer and passivation layer, forming a PR cavity for depositing metal structure by lithography process, depositing metal structure on the top metal layer of micromachined structure by Electroless plating, polishing process and etching process. The method aims at strengthening structures and minimizing CMOS-MEMS device size. Furthermore, this method can also be applied to motion sensors such as accelerometer or gyroscope, which can enhance sensitivity and capacitive value, and deal with curl issues for suspended CMOS-MEMS devices.

### DESCRIPTION OF RELATED ART

System on chip (SOC) technology has gradually accommodated CMOS-MEMS products such as micro sensors, micro actuators or micro structures, which assemble mechanical components with electronic systems in a single chip.

The integrated CMOS-MEMS sensors highly integrate IC processes, MEMS processes and packaging processes, which cause the whole processes of integrated CMOS-MEMS sensors become complicated. The bottlenecks of current CMOS-MEMS technology include: (a) residual stress, caused by the manufacturing temperature and pressure in thin film process, the characteristics of materials, and film deposition of atomic arrangement, can jeopardize CMOS-MEMS devices' performances and structures. The current industries still have no better method to conquer residual issues; (b) the standard CMOS process provides fixed recipes including the layer thickness, materials, stacked-layer arrangement and process rules, and devotes highly to the requirements of electronic circuits, rather than micromachined structure design needs; thus, the required recipes of micromachined structure may not be completely achieved by standard semiconductor process; (c) the processes of combining micromachined structure with electronic circuits in one chip are complex and difficult, which increase the total costs; (d) mechanical properties can not be reached. Usually micro motion sensors such as accelerometers, gyroscopes, etc require heavier mass and larger capacitive values to provide the higher sensitivity. Because of consideration for stability, yield rate and price, the current semiconductor process may not achieve certain requirements of CMOS-MEMS micro-machined devices.

Domestic and foreign scholars, and some international companies have brought up the following methods to increase sensitivity of MEMS motion sensors; (a) using Silicon On Insulation (SOC) wafer to be structural substrate, but high cost; (b) employing electroforming to increase the weight of proof mess, which is difficult to control the quality, height and uniformity of electroformed films, and damages the performance of circuits; (c) employing sputtering technology to deposit extra film to gain the weight of proof mess, but low deposition rate and not cost-effective; (d) utilizing etching technology such as dry and wet etching to form bulk machining, but complicated process and high cost.

In order to solve the foregoing issues, the present invention will provide a method to enhance sensitivity and to strengthen micro structures for CMOS-MEMS micro-machined devices, which utilizes Electroless plating on the micromachined structures. Here, the CMOS-MEMS micromachined devices consist of at least one micromachined structure and one metal layer for deposited region, and can further add measuring circuits and packaging seal ring. Wherein, the micromachined structure comprises at least one proof mass structure and one pair of comb-finger structure. By Electroless plating, it can deposit extra metal structure layer selectively on the deposited region of micromachined structure, which can enhance the strength of micro structure, gain the weight of proof mass, improve the sensitivity, increase the capacitive value, minimize the size and reduce the level of curl for suspended micro structures.

Electroless plating employs its oxidation-reduction reaction to deposit without external electric field. As long as the temperature and PH value of plating bath can be maintained well, the deposited metal structure can have good uniformity, high corrosion resistance, low residue stress and high density.

### SUMMARY

The present invention provide a method which employs Electroless plating to deposit extra metal structures on the micromachined structure of CMOS-MEMS micromachined devices. The deposited metal structure can strengthen suspended structures of the original device, and further compensate the residual stress of the suspended structures because it can provide different level of compressive or tensile stress by operating parameters of the plating bath such as temperature, PH value and ingredients.

Another aspect of this invention is to enhance the performances of micro mention sensors including gyroscopes, accelerometers etc by employing Electroless plating to deposit metal structure on micro structures. Depositing metal structure on the proof mass of the micromachined structure can provide heavier weight, which can increase the displacement of the movement, sensitivity, and can further occupy less proof mass size. Furthermore, Depositing metal structure on the capacitive sensing electrode such as comb-fingers can increase overlap areas of sensing electrode and provide higher capacitive value.

### BRIEF DESCRIPTION OF DRAWINGS

The detailed drawings of this invention will be fully understood from the following descriptions wherein:

FIG. 1 is a schematic process flow for increasing weight of proof mass, sensitivity and displacement of movement for CMOS-MEMS devices.

FIG. 2(a) is the simulated results of the relationship between the weight of the proof mass and the different thickness of deposited nickel structure.

FIG. 2(b) is the simulated results of the relationship between nickel structure and displacement of movement.

FIG. 3 is a schematic process flow for enhancing capacitance of CMOS-MEMS devices.

FIG. 4 is the simulated result of relationship between the capacitive value and deposited nickel structure.

FIG. 5 is a general schematic representation of a process according to the invention.

The following description should be read with reference to the drawings, in which like elements in different drawings are numbered in like fashion. The drawings, which are not necessarily to scale, depict selected embodiments and are not intended to limit the scope of the invention. Although examples of construction, dimensions, and materials are illustrated for the various elements, those skilled in the art will recognize that many of the examples provided have suitable alternatives that may be utilized. While the fabrication of micromachined sensors such as MEMS gyroscopes, MEMS accelerometers and electrostatic actuators is specifically discussed, it should be understood that the fabrication steps and structures described herein can be utilized in other MEMS devices, as desired.

### DETAILED DESCRIPTION

The purpose of this invention aims at providing a method to strengthen micro structures, increasing sensitivity and capacitance, compensating suspended micromachined structure for residual stress, and occupying less area size for CMOS-MEMS devices. This invention comprises the steps of: (a) defining the depositing regions by passivaition layer with metal layer or by metal layer only; (b) building photoresist (PR) cavity for forming vertical deposited metal structure by photolithography process; (c) depositing single layer or multiple layers of metal structure which can be Au, Co, Rh, Ni, Ag, Cu, Pd, Sn and Zn by Electroless plating; (d) removing PR; (e) employing dry or wet etching to suspend micromachined structure. All of the foregoing processes are based on existing and standard processes such as photolithography process, deposition process, etching process, CMP process etc.

### EMBODIMENT 1

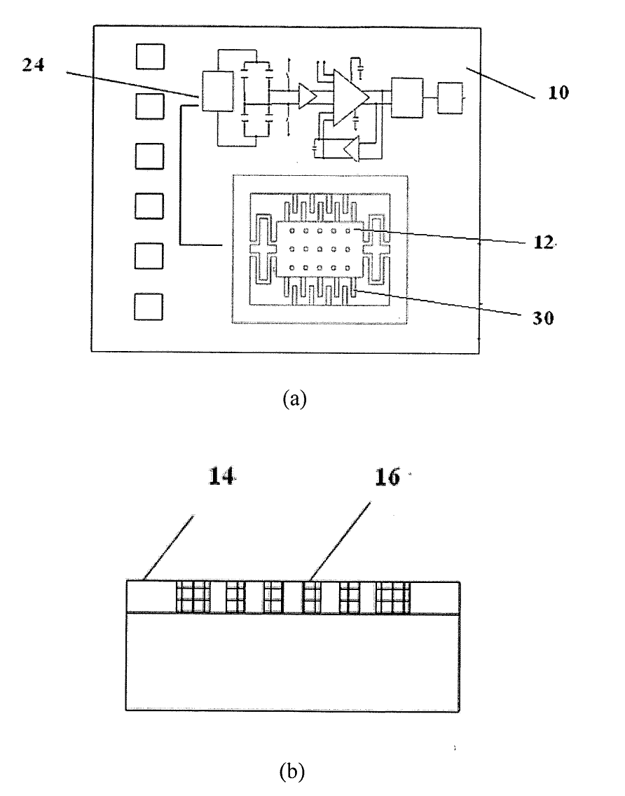

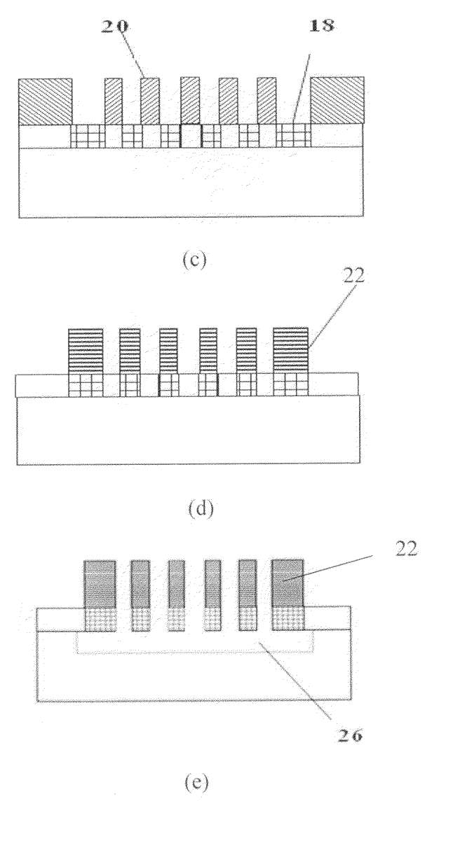

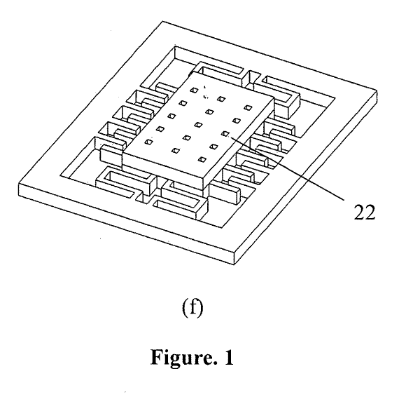

Referring to FIG. 1, it illustrates the schematic process flow for increasing the weight of proof mass 12, enhancing the sensitivity, strengthening the micro structures, minimizing the size, and compensating suspended micromachined structure for residual stress, which can apply to CMOS-MEMS devices 10 such as accelerometer, gyroscope, micro motion sensors, etc. The process of this embodiment comprises the following steps of:

Step 1, designing CMOS-MEMS devices and defining the deposited region for deposited metal structure. Employ standard semiconductor process such as 0.35 μm CMOS processes to produce CMOS-MEMS device 10 which contains micromachined structures, proof mass, comb-finger structures and the deposited regions on the proof mass of micromachined structures by the top metal layer 16 and passivation layer 14, shown as FIG. 1(b). Further, CMOS-MEMS devices 10 can contain amplifier, drivers and measuring circuits 24.

Step 2, patterning cavities through photolithography process. Employ the photolithography process to fabricate PR cavity 20, which can assist the deposited metal structure 22 on the deposited region 18 to grow vertically, shown as FIG. 1(c).

Step 3, depositing nickel structures by Electroless plating Before depositing nickel structures, the deposited regions 18 composed of the top metal layer 16 and passivation layer 14 has to do surface treatment, Zincate of Aluminum alloy. By Electroless plating, the nickel atoms in the plating bath can deposit on the deposited regions 18, and grow inside the PR cavity 20 to form nickel structure 22. Generally, the working temperature of plating bath is around 80° C. to 100° C. which would not damage micromachined structure and circuits 24, shown as FIG. 1(d). After depositing nickel structure 22, the PR cavity 20 has to be removed.

Step 4, polishing the nickel structures Employ polish process to control thickness and uniformity of nickel structure 22.

Step 5, releasing suspended micromachined structure Employ etching technology to release suspended micromachined structures 26, shown as FIG. 1(e).

Usually the residual stresses result from a variety of reasons, including multi-layers of stacked thin film materials, different thermal and crystalline properties, and heat treatment. In fabricating processes, especially in the CMOS fabrication process, the stress variation through stacking multiple thin film materials can be very complex and can vary between compressive and tensile stresses from layer to layer. Consequently, the micromachined structures will appear curl situation after suspending micromachined structures. By this invention, the deposited nickel structure 22 can compensate the suspended micromachined structures for residual stress, which can improve curl issues.

The advantages of this invention include: (a) CMOS-MEMS device 10 and the deposited regions 18 can be fabricated by standard process without increasing manufacturing costs; (b) the materials of the deposited metal structure 22 can be Au, Co, Rh, Ni, Ag, Cu, Pd, Sn and Zn, depending on the requirements of COS-MEMS device 10 such as weight, strength and so on. Further the deposited structure can be multi-layers with different materials; (c) generally, the existing CMOS-MEMS motion sensors have low weight of proof mass and poor sensitivity problems. By Electroless plating, the deposited nickel structure 22 can increase the weight of proof mass and improve the sensitivity of CMOS-MEMS motion sensors further; (d) the deposited nickel structure 22 can compensate the suspended micromachined structures for residual stress to improve curl issues; (e) the materials and thickness of thin films in current semiconductor process have been limited, which seriously affect the performances of CMOS-MEMS sensor such as low capacitance, poor sensitivity, curl issues etc. By the deposited nickel structure 22, the weight of proof mass 12 and sensitivity can be enhanced without using high-cost SOI fabrication process or needing complex dry etching process to keep thicker silicon mass under the suspended structure or occupying large size; (f) the deposited structures can be multi-layers with different materials, by Electroless plating, which can increase the flexibility of designing CMOS-MEMS sensor.

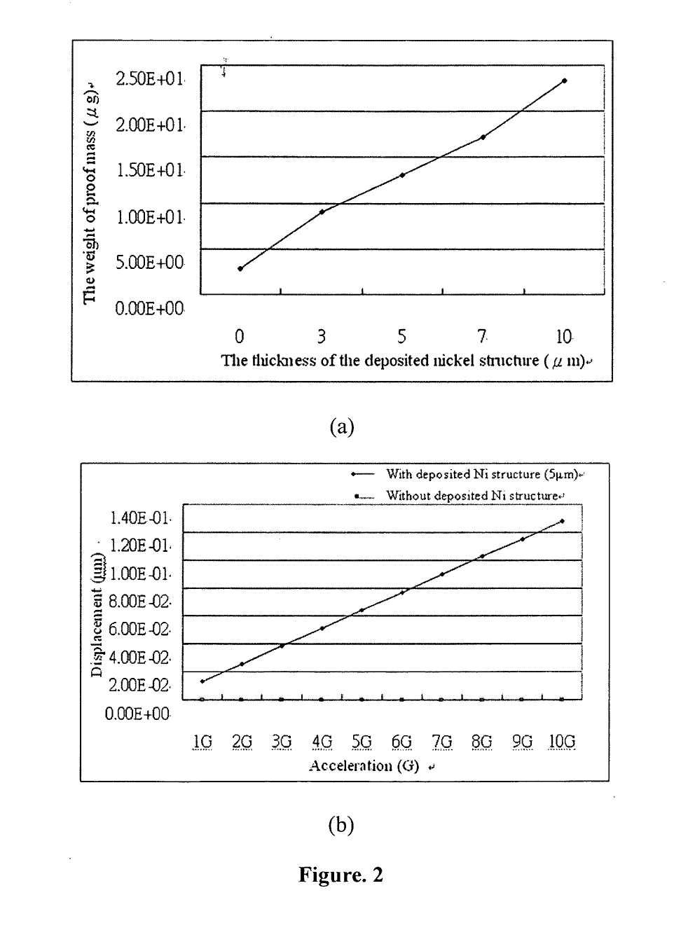

The simulated results of the relationship between the weight of proof mass and the different thickness (3 μm, 5 μm, 7 μm and 10 μm) of the deposited nickel structure are shown in FIG. 2 (a). And the simulated results of the relationship between nickel structure and displacement of movement are shown in FIG. 2 (b). According to simulated results, the weight of proof mass and the displacement of movement can be increased more than 3 times, compared with the original of CMOS-MEMS motion sensor.

### EMBODIMENT 2

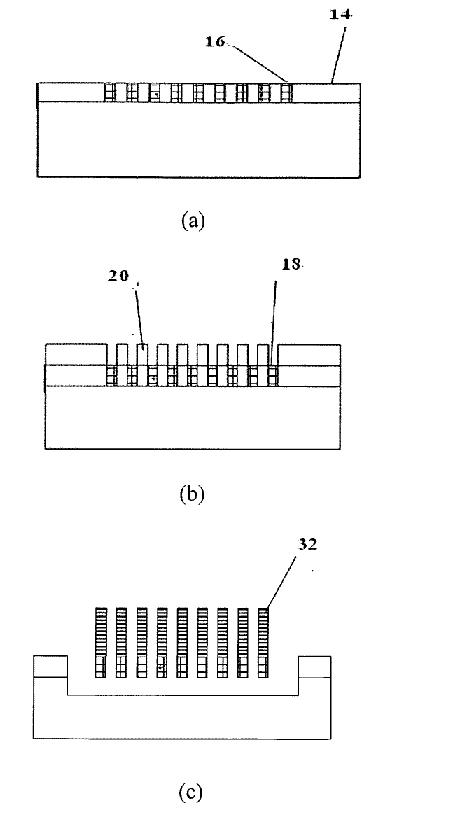

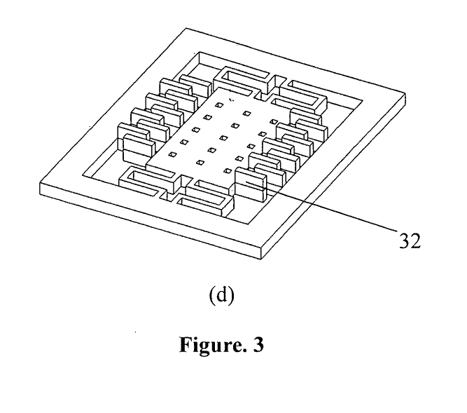

Referring to FIG. 3, it illustrates the schematic process flow for depositing the nickel structures 32 on the comb finger structures 30, which can increase the overlap areas and sensing capacitance. The process flow is similar to Embodiment 1, including defining the deposited region by metal layer and psssivation layer, lithography process to build PR cavity, depositing nickel structures by Electroless plating, removing the PR, polishing the nickel structures and releasing suspended micromachined structure.

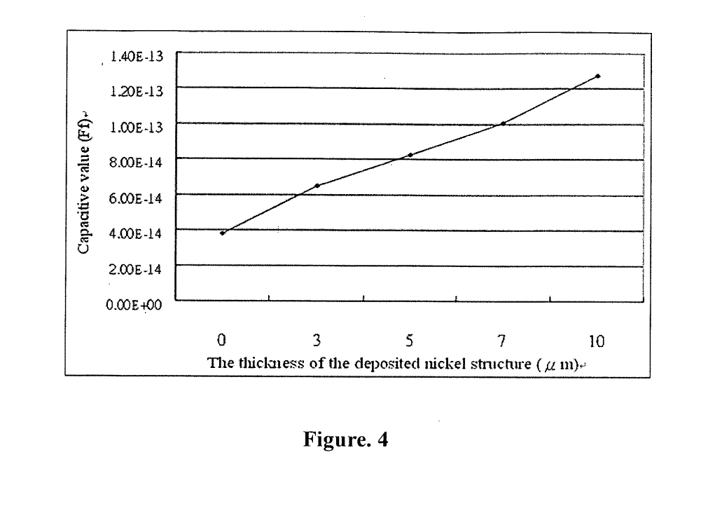

The simulated results of the relationship between the sensing capacitance and different thickness (3 μm, 5 μm, 7 μm and 10 μm) of the deposited nickel structures 32 are shown in FIG. 4. According to simulated results, the sensing capacitance can increase at least 2 times with the deposited nickel structures 32 on the comb finger structures 30.

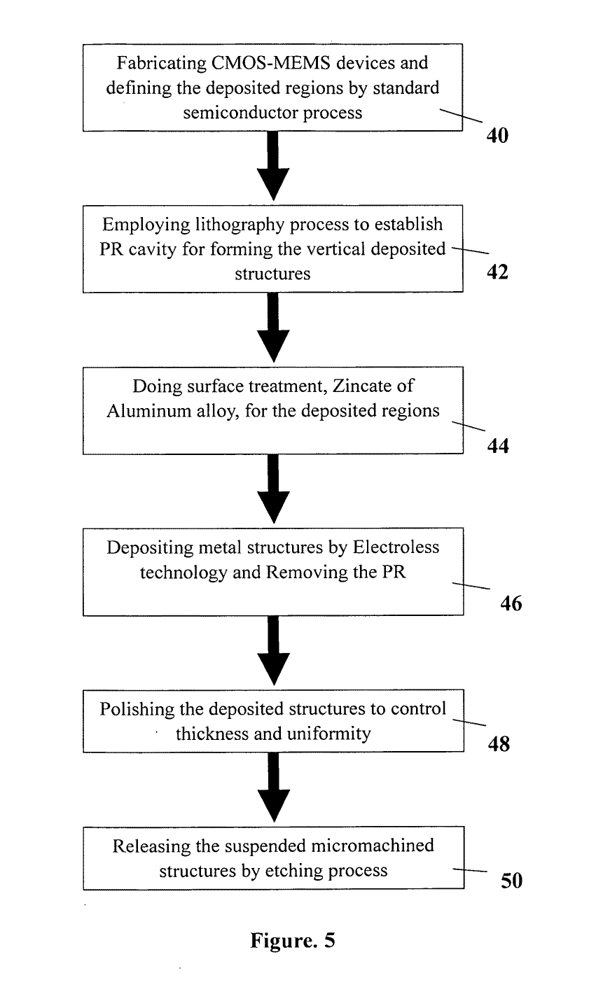

Referring to FIG. 5, it illustrates a general schematic representation of a process for this invention, which comprises steps of: (a) fabricating CMOS-MEMS devices and defining the deposited regions by standard semiconductor process 40; (b) employing lithography process to establish PR cavity for forming the vertical deposited structures 42; (c) doing surface treatment, Zincate of Aluminum alloy, for the deposited regions 44; (d) depositing metal structures by Electroless plating and removing the PR 46; (e) polishing the deposited structures to control thickness and uniformity 48. The polishing process is optional, if the precision of dimension is not a requirement or the thickness of the deposited structures is under 5 μm; (f) releasing the suspended micromachined structures by etching process 50.

In summary, the advantages of this invention include: (a) enhancing the sensitivity, capacitance and strength of CMOS-MEMS devices; (b) dealing with curl issues for suspended micromachined structures; (c) reducing the size of CMOS-MEMS devices; (d) reducing the process cost and establishing by standard semiconductor process.

Having thus described the several embodiments of the present invention, those of skill in the art will readily appreciate that other embodiments may be made and used which fall within the scope of the claims attached hereto. Numerous advantages of the invention covered by this document have been set forth in the foregoing description. It will be understood that this disclosure is, in many respects, only illustrative. Changes may be made in details, particularly in matters of shape, size and arrangement of parts without exceeding the scope of the invention.

What is claimed is:

1. A CMOS-MEMS micromachined device comprising:
a micromachined structure comprising at least one proof mass, and at least one metal layer on the top of the proof mass;
at least one layer of the deposited metal structure on the micromachined structure by Electroless plating.

2. The device of claim 1, wherein the CMOS-MEMS micromachined device is a micro motion sensor.

3. The device of claim 1, wherein the CMOS-MEMS micromachined device is a micro actuator.

4. The device of claim 1, wherein the CMOS-MEMS micromachined device is a micro switch.

5. The device of claim 1, wherein the micromachined structure is suspended.

6. The device of claim 1, wherein the micromachined structure is non-suspended.

7. The device of claim 1, wherein the micromachined structure further comprises at least one pair of comb figure structure.

8. The device of claim 1, wherein the deposited metal structure is single layer.

9. The device of claim 1, wherein the deposited metal structure are multi-layers.

10. The device of claim 8, wherein the deposited metal structure are formed with combination of at least two of different materials such as Au, Co, Rh, Ni, Ag, Cu, Pd, Sn and Zn.

11. A method for enhancing CMOS-MEMS micromachined device's strength and sensitivity, comprising the steps of:
providing a micromachined structure, comprising at least one proof mass structure;
providing a deposited region on the micromachined structure;
providing a deposited metal structure on the deposited region by Electroless plating;
wherein the deposited metal structure is on the deposited region of the micromachined structure to enhance sensitivity, strength and capacitive value of CMOS-MEMS micromachined device.

12. The method of claim 11, wherein the micromachined structure further comprises at least one pair of comb figure structure.

13. The method of claim 11, wherein the deposited region is defined by the top metal layer with passivation layer.

14. The method of claim 11, wherein the deposited region is defined by the top metal layer with photoresist.

15. The method of claim 11, wherein the deposited region is further comprising the step of surface treatment.

16. The method of claim 11, wherein the deposited metal structure is further comprising the step of polishing process.
